(19) United States
(12) Patent Application Publication
(10) Pub. No.: US 2026/0353901 A1
(43) Pub. Date: Nov. 5, 2026

(54) LIGHT EMITTING MODULE

(71) Applicant: Seoul Viosys Co., Ltd., Ansan-si (KR)

(72) Inventor: Jina LEE, Ansan-si (KR)

(73) Assignee: Seoul Viosys Co., Ltd., Ansan-si (KR)

(21) Appl. No.: 19/661,270

(22) Filed: Apr. 28, 2026

Related U.S. Application Data
(60) Provisional application No. 63/797,383, filed on Apr. 30, 2025.

(51) Int. Cl. H10H 29/85; H10H 20/813; H10H 29/24; H10H 29/80; H10H 29/853

(52) U.S. Cl. CPC H10H 29/857; H10H 20/8131; H10H 29/24; H10H 29/8321; H10H 29/8508; H10H 29/853

(57) ABSTRACT

A light emitting module includes one or more light emitting devices, a driver for driving the light emitting devices, and a substrate on which the driver is mounted, in which the light emitting device is disposed on a first surface of the driver to be vertically overlapped with the driver.

### CROSS-REFERENCE TO RELATED APPLICATIONS

This application is based upon and claims the benefit of U.S. Provisional Patent Application No. 63/797,383 filed Apr. 30, 2025, the entire contents of which are incorporated herein by reference.

### TECHNICAL FIELD

The present invention relates to a light emitting module including a light emitting device.

### BACKGROUND ART

A light emitting diode (LED) is one of light emitting devices that emit light when current is applied. Recently, the light emitting diode has been widely used in various technical fields such as display apparatuses, vehicle lamps, and general lighting. Moreover, the light emitting diode has advantages of long life, low power consumption, and fast response speed. By taking full advantage of these advantages, LEDs have been rapidly replacing a conventional light source. For example, a display apparatus using the light emitting diode may be obtained by forming structures of individually grown red R, green G, and blue B light emitting diodes (LEDs) on a final substrate.

A display apparatus including the light emitting diode can be installed in various locations such as exterior walls of buildings, indoor columns, indoor side walls, or others to provide a transparent display while displaying videos or images on the screen. The transparent display may be implemented by disposing light emitting diodes on a transparent substrate, and may exhibit various degrees of transparency depending on a design method, such as LED strips or meshes.

### DISCLOSURE

### Technical Problem

The present invention may provide a light emitting module having high transparency by maximizing an area through which light is transmitted.

The present invention may provide a light emitting module capable of achieving high resolution while improving transparency by disposing a light emitting device and a driver in a vertically overlapping manner.

The present invention may provide a light emitting module that is transparent and has high luminance, thereby being applicable to indoor environments.

The present invention may provide a light emitting module that is configured to minimize the bezel at an edge of a display.

The present invention may provide a light emitting module that is configured to reduce degradations of a light emitting device and a driver of a light emitting apparatus due to heat, and to improve reliability thereof.

The present invention may provide a light emitting module that is highly reliable and easy to manufacture.

The present invention may provide a light emitting module that is configured to secure mechanical durability by enhancing structural stability.

### Technical Solution

A light emitting module according to an embodiment of the present invention may include one or more light emitting devices, a driver for driving the light emitting devices, and a substrate on which the driver is mounted.

In an embodiment, the light emitting device may be disposed on a first surface of the driver to vertically overlap with the driver.

In an embodiment, the driver may include a first electrode portion disposed on the first surface and connected to a device electrode of the light emitting device, and a second electrode portion disposed on a second surface opposite to the first surface and connected to a substrate electrode of the substrate.

In an embodiment, a plurality of light emitting devices may be spaced apart on the first surface of the driver.

In an embodiment, the first electrode portion may include a first common electrode commonly connected to the plurality of light emitting devices, and a plurality of first individual electrodes respectively connected to the plurality of light emitting devices.

In an embodiment, the light emitting device may include a plurality of light emitting stacks that are vertically stacked and emit light of peak wavelengths different from one another.

In an embodiment, the first electrode portion may include a first common electrode commonly connected to the plurality of light emitting stacks, and a plurality of first individual electrodes respectively connected to the plurality of light emitting stacks.

In an embodiment, an area occupied by a light emitting device disposed on the first surface of the driver may be smaller than that of the first surface of the driver.

In an embodiment, the light emitting module may further include a molding part covering the light emitting device and the driver.

In an embodiment, the driver may include a first electrode portion disposed on the first surface and connected to the device electrode of the light emitting device, and a second electrode portion disposed on the first surface and connected to the substrate electrode of the substrate.

In an embodiment, the driver may face the substrate on the second surface opposite to the first surface.

In an embodiment, the light emitting module may further include a side electrode portion connecting the second electrode portion and the substrate electrode along a side surface of the driver.

In an embodiment, an insulation layer disposed between the side surface of the driver and the side electrode portion may be further included.

In an embodiment, the side electrode portion may extend to the second surface of the driver.

In an embodiment, when an area of a rectangular region having a width and a height of 2 inches each is referred to as a reference area, a transparency of the light emitting module defined by Equation 1 may be 80% or more.

In an embodiment, an interval between adjacent drivers may be between 1 and 3 times of a length of one side of the driver.

A light emitting module according to an embodiment of the present invention may include one or more light emitting devices, a driver for driving the light emitting devices, and a substrate on which the light emitting devices and the driver are mounted.

In an embodiment, the light emitting device may be disposed on a first surface of the substrate, and the driver may be disposed on a second surface opposite to the first surface of the substrate to be perpendicularly overlapped with the light emitting device in plan view.

In an embodiment, the driver may include a first electrode portion disposed on a first surface of the driver and connected to the light emitting device, and a second electrode portion disposed on the first surface of the driver and connected to the substrate.

In an embodiment, the substrate may include a first substrate electrode disposed on the first surface of the substrate and connected to a device electrode of the light emitting device, a second substrate electrode disposed on the second surface of the substrate and connected to the second electrode portion, and a third substrate electrode disposed on the second surface and connected to the first electrode portion.

In an embodiment, a through hole vertically passing through the substrate is formed, and the substrate may further include a through electrode connecting the first substrate electrode and the third substrate electrode through the through hole.

In an embodiment, a filler that fills a space between the substrate and the driver may be further included.

A light emitting module according to an embodiment of the present invention may include a first substrate, a driver mounted on a surface of the first substrate and driving a light emitting device, a second substrate opposite to the first substrate at a distance, one or more light emitting devices mounted on a surface of the second substrate, one or more connection electrodes disposed between the first substrate and the second substrate to electrically connect the driver and the light emitting devices, and a molding layer filling a space between the first substrate and the second substrate.

In an embodiment, at least a portion of the light emitting device may be perpendicularly overlapped with the driver in plan view.

### Advantageous Effect

The present invention may provide a light emitting module having high transparency by maximizing an area through which light is transmitted.

The present invention may provide a light emitting module capable of achieving high resolution while improving transparency by disposing a light emitting device and a driver in a vertically overlapping manner.

The present invention may provide a light emitting module that is transparent and has high luminance, thereby being applicable to indoor environments.

The present invention may provide a light emitting module that is configured to minimize the bezel at an edge of a display.

The present invention may provide a light emitting module that is configured to reduce degradations of a light emitting device and a driver of a light emitting apparatus due to heat and to improve reliability thereof.

The present invention may provide a light emitting module that is highly reliable and easy to manufacture.

The present invention may provide a light emitting module that is configured to secure mechanical durability by enhancing structural stability.

### BRIEF DESCRIPTION OF THE DRAWINGS

FIG. 1 is a cross-sectional view showing a light emitting module according to a first embodiment of the present invention.

FIG. 2 is a circuit diagram showing an electrical connection between a light emitting device and a driver of the light emitting module according to the first embodiment of the present invention.

FIG. 3A is a top view showing the light emitting device and the driver of FIG. 1.

FIG. 3B is a bottom view of FIG. 3A.

FIG. 4 is a cross-sectional view in A-A′ direction of FIG. 3A.

FIG. 5 is a plan view showing the light emitting module of FIG. 1.

FIG. 6 is a modified example of the light emitting device and the driver of FIG. 3A.

FIG. 7 is a cross-sectional view of FIG. 6.

FIGS. 8 through 10 are other modified examples of the light emitting device and the driver of FIG. 4.

FIG. 11 is a cross-sectional view showing a light emitting module according to a second embodiment of the present invention.

FIG. 12 is a modified example of FIG. 11.

FIG. 13 is a cross-sectional view showing a light emitting module according to a third embodiment of the present invention.

FIG. 14 is a cross-sectional view showing a light emitting module according to a fourth embodiment of the present invention.

FIG. 15 is a cross-sectional view showing a light emitting module according to a fifth embodiment.

FIG. 16 shows an example of an arrangement of a connection electrode in plan view.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a preferred embodiment of a light emitting module of the present invention will be described in detail with reference to the attached drawings.

The light emitting module according to the present invention may be applied to various light emitting systems. For example, the light emitting system may be a vehicle light emitting system or display apparatus.

In the vehicle light emitting system, the light emitting module may be disposed on one side of a light transmitting portion disposed in one region of a vehicle frame. For example, the light emitting module may be a brake light (HMSL: a high mounted stop lamp) installed in a vehicle. In this case, the light emitting system may have different transmittances in a region where the light emitting module is disposed and in the light transmitting portion. In addition, the light emitting module may be configured as a display, a headlamp, a brake light, an interior light, or others installed in the vehicle.

The display apparatus may be a lighting apparatus, translucent glass, smart glass, smart mirror, electronic picture frame, or others. In this case, the display apparatus may further include a frame installed at an edge of the light emitting module to protect the light emitting module. To increase a transparency of the display apparatus, power may be supplied to the light emitting module by a wire disposed in one region of the frame. The frame may be omitted as an optional configuration.

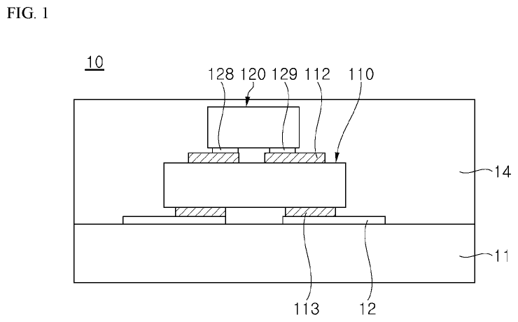

FIG. 1 is a cross-sectional view showing a light emitting module 10 according to a first embodiment of the present invention. Referring to FIG. 1, the light emitting module 10 may include one or more light emitting devices 120, a driver 110 for driving the light emitting devices 120, and a substrate 11 on which the driver 110 is mounted.

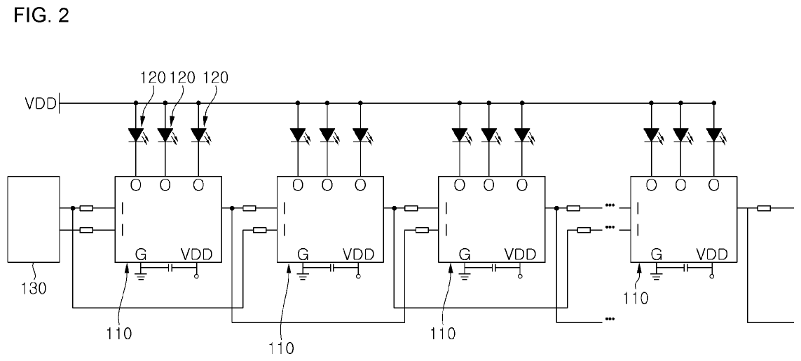

FIG. 2 is a circuit diagram showing an electrical/signal connection of the light emitting module 10, and the driver 110 may be an electronic component (IC, Integrated Circuit) that stably supplies power to the light emitting device 120 to control operations such as a brightness of the light emitting device 120. The driver 110 may stably control a voltage or current applied to the light emitting device 120, perform dimming control in a manner such as PWM or the like, and include a protection circuit that protects the light emitting device 120 in situations such as overvoltage/overcurrent/short circuit.

The driver 110 may be a single-channel driver that controls one light emitting device 120 or a light emitting group including several light emitting devices 120. Alternatively, the driver 110 may be a multi-channel driver that controls multiple light emitting devices 120 or multiple light emitting groups. The driver 110 may be connected to the light emitting device 120 through an output channel O.

FIG. 2 illustrates a structure in which one driver 110 controls three light emitting devices 120, but a number of light emitting devices 120 or light emitting groups controlled by one driver 110 may be set in various ways.

The driver 110 may be connected to a controller 130 through an input channel I. The controller 130 may be configured to control the driver 110, and may be implemented as an MCU, FPGA, ASIC, or the like. The controller 130 may control a plurality of drivers 110. The controller 130 may transmit signals such as data, timing (clock), PWM signal, communication, or others to the driver 110 through the input channel I.

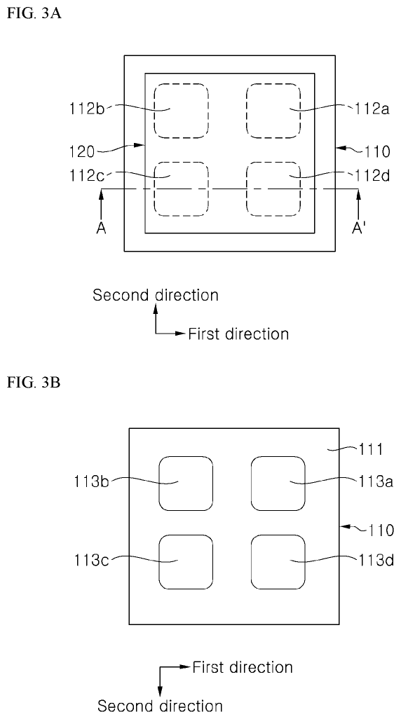

FIG. 3A is a top view showing the light emitting device 120 and driver 110 of FIG. 1.

A surface of the driver 110 may be an upper surface, and may have a first direction length and a second direction length perpendicular thereto. When a surface of the driver 110 is referred to as a first surface, a bottom surface opposite to the first surface may be referred to as a second surface. The driver 110 may have a hexahedral shape with the first surface as the top surface and the second surface as the bottom surface, but this is merely exemplary and a shape and a size of the driver 110 may be designed in various ways. Sizes of areas of the first and second surfaces of the driver 110 may also be designed in various ways.

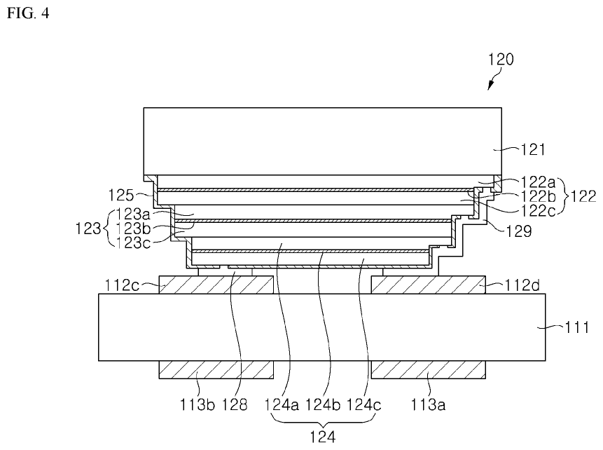

Referring to FIG. 4, a light emitting device 120 may be a light emitting diode including a substrate 121 and light emitting stacks 122, 123, and 124 disposed on a surface of the substrate 121. The light emitting device 120 of FIG. 4 is merely an example of a light emitting diode, and the light emitting diode is not limited to a specific structure.

The substrate 121 may be a growth substrate for growing a gallium nitride semiconductor layer, such as a sapphire substrate, a silicon substrate, a SiC substrate, a spinel substrate, a Ga₂O₃ substrate, or others. The substrate 121 is not limited to a specific type as long as it is a substrate capable of growing the nitride semiconductor layer. The substrate 121 may be removed after the semiconductor layer is grown.

The light emitting stacks 122, 123, and 124 may be semiconductor layers, and may include first conductivity type semiconductor layers 122a, 123a, and 124a, second conductivity type semiconductor layers 122c, 123c, and 124c, and active layers 122b, 123b, and 124b disposed between the first conductivity type semiconductor layers 122a, 123a, and 124a and the second conductivity type semiconductor layers 122c, 123c, and 124c.

The first conductivity type semiconductor layers 122a, 123a, and 124a may be semiconductor layers grown on a surface of the substrate 121, and may include a phosphide or nitride semiconductor such as (Al, Ga, In) P or (Al, Ga, In) N. In addition, the first conductivity type semiconductor layers 122a, 123a, and 124a may be doped as an n-type by including one or more impurities such as Si, C, Ge, Sn, Te, Pb, or others. The present invention is not limited thereto, and as another example, the first conductivity type semiconductor layers 122a, 123a, and 124a may be doped with an opposite conductivity type including a p-type dopant. Furthermore, the first conductivity type semiconductor layers 122a, 123a, and 124a may be formed as a single layer or multiple layers.

The active layers 122b, 123b, and 124b are light emitting layers respectively disposed on one side of the first conductivity type semiconductor layers 122a, 123a, and 124a, may include a phosphide or nitride semiconductor such as (Al, Ga, In) P or (Al, Ga, In) N, and may be grown on the first conductivity type semiconductor layers 122a, 123a, and 124a using a technology such as MOCVD, MBE, HVPE, or the like. In addition, the active layers 122b, 123b, and 124b may include a quantum well structure (QW) including at least two barrier layers and at least one well layer, and furthermore, may include a multi quantum well structure (MQW) including a plurality of barrier layers and a plurality of well layers. Wavelengths of light emitted from the active layers 122b, 123b, and 124b may be adjusted by controlling a composition ratio of materials forming the well layer. In this case, the well layers may include a same element in common, for example, In.

The second conductivity type semiconductor layers 122c, 123c, and 124c may be a semiconductor layer respectively disposed on one side of the active layers 122b, 123b, and 124b. The second conductivity type semiconductor layers 122c, 123c, and 124c may include a phosphide or nitride semiconductor such as (Al, Ga, In) P or (Al, Ga, In) N. The second conductivity type semiconductor layers 122c, 123c, and 124c may be doped with a conductivity type opposite to that of the first conductivity type semiconductor layers 122a, 123a, and 124a. For example, the second conductivity type semiconductor layers 122c, 123c, and 124c may be doped as a p-type by including an impurity such as Mg.

The light emitting device 120 may have a light exiting surface formed on sides of the first conductivity type semiconductor layers 122a, 123a, and 124a or the second conductivity type semiconductor layers 122c, 123c, and 124c through which light is emitted. For example, light generated in the active layers 122b, 123b, and 124b may be emitted to the outside by passing through the first conductivity type semiconductor layers 122a, 123a, and 124a, or emitted to the outside by passing through the second conductivity type semiconductor layer 122c, 123c, and 124c. A concave-convex structure for increasing light extraction efficiency may be formed on a surface of the first conductivity type semiconductor layers 122a, 123a, and 124a or a surface of the second conductivity type semiconductor layer 122c, 123c, and 124c.

FIG. 4 exemplary illustrates that the light emitting device 120 includes a plurality of light emitting stacks 122, 123, and 124 that are vertically stacked, but the present invention is not limited thereto. For example, the light emitting device 120 may include one light emitting stack 122, 123, or 124 or two light emitting stacks 122, 123, or 124.

Back to FIG. 4, in detail, the light emitting device 120 may include a first light emitting stack 122, a second light emitting stack 123, and a third light emitting stack 124 that emit light of peak wavelengths different from one another. Light emitted from the third light emitting stack 124 may pass through the second and first light emitting stacks 123 and 122 and be emitted to the outside.

For example, the first light emitting stack 122 may emit red light, the second light emitting stack 123 may emit green light, and the third light emitting stack 124 may emit blue light. This is merely exemplary and the present invention is not limited thereto. It is, of course, also possible that the first light emitting stack 122 emits blue light and the third light emitting stack 124 emits red light.

An adhesive layer for adhesion may be disposed between the first through third light emitting stacks 122, 123, and 124.

The light emitting device 120 may include an insulation layer 125 covering the first through third light emitting stacks 122, 123, and 124. The insulation layer 125 may include an organic or inorganic insulation material, for example, polyimide, SiO2, SiNx, Al₂O₃, or others. In addition, the insulation layer 125 may include a single-layer structure or a multi-layer structure. For example, the insulation layer 125 may include a distributed Bragg reflector (DBR) as an example of a multi-layer structure.

In addition, the light emitting device 120 may include a plurality of device electrodes 128 and 129. One of the device electrodes 128 and 129 may be a common device electrode 129 that is commonly connected to the first through third light emitting stacks 122, 123, and 124. Except for the common device electrode 129, remaining electrodes may be individual device electrodes 128 individually connected to each of the light emitting stacks 122, 123, and 124. In a case of FIG. 3, since the light emitting device 120 includes three light emitting stacks 122, 123, and 124, the individual device electrodes 128 may also be provided in three.

The common device electrode 129 may be commonly in contact with the first conductivity type semiconductor layers 122a, 123a, and 124a of each of the light emitting stacks 122, 123, and 124 through an opening of the insulation layer 125. Each of the individual device electrodes 128 may be in contact with the second conductivity type semiconductor layers 122c, 123c, and 124c of corresponding light emitting stacks 122, 123, and 124 through the opening of the insulation layer 125.

In this case, the light emitting device 120 may be disposed on the first surface of the driver 110 to be vertically overlapped with the driver 110. As the light emitting device 120 is vertically overlapped with the driver 110, there are advantages that the transparency of the light emitting module may be prevented from being reduced by the light emitting device 120, and a wider transparent region may be secured. In particular, since a connection line for connecting the driver 110 and the light emitting device 120 may be omitted, there is an advantage of being able to further increase the transparency.

In this case, the driver 110 may include a first electrode portion (112: 112a, 112b, 112c, 112d) disposed on the first surface of the driver 110 and connected to the device electrodes 128 and 129 of the light emitting device 120. The first electrode portion 112 (112a, 112b, 112c, 112d) may be provided in a plurality.

One of the first electrode portions 112a, 112b, 112c, and 112d may be a first common electrode 112d corresponding to the common device electrode 129 of the light emitting device 120. Remaining electrodes may be first individual electrodes 112a, 112b, and 112c respectively corresponding to the individual device electrodes 128 of the light emitting device 120.

Meanwhile, the driver 110 may be mounted on the substrate 11. The substrate 11 may be a transmissive substrate. For example, the substrate 11 may be a substrate having transmissivity, such as sapphire, PMMA (Polymethyl Methacrylate), PC (Polycarbonate) resin, COP (Cyclo Olefin Polymer), acrylic resin, PE (Polyethylene), PET (Polyethylene Terephthalate) film, epoxy resin, glass, or others, without being limited to a specific type.

The driver 110 may be disposed on a surface of the substrate 11. In this case, the substrate 11 may include a substrate electrode 12 for being electrically connected to the driver 110. The driver 110 may include a second electrode portion 113 (113a, 113b, 113c, 113d) disposed on the second surface opposite to the first surface and connected to the substrate electrode 12 of the substrate 11. The second electrode portion 113 (113a, 113b, 113c, 113d) may be provided in a plurality. Accordingly, as illustrated in FIG. 1, the substrate 11, the driver 110, and the light emitting device 120 are sequentially stacked, and the light emitting device 120 may be disposed on the first surface of the driver 110 to be vertically overlapped with the driver 110.

In this case, the driver 110 may include a body portion 111, and the body portion 111 may form the first surface and the second surface of the driver 110. A first electrode portion 112 may be disposed on the first surface of the body portion 111, and a second electrode portion 113 may be disposed on the second surface.

An area occupied by the light emitting device 120 disposed on the first surface of the driver 110 may be smaller than that of the first surface of the driver 110. Even when a plurality of light emitting devices 120 are disposed in a transverse direction on a surface of the driver 110, an area occupied by entire light emitting devices 120 may be smaller than that of the first surface of the driver 110.

Referring back to FIG. 1, the light emitting module 100 may further include a molding 14 that covers the light emitting device 120 and the driver 110.

The molding 14 is a layer that covers at least portions of side surfaces or upper surfaces of the light emitting device 120 and the driver 110, and may transmit at least a portion of light emitted from the light emitting device 120. The molding 14 may cover at least portions of the light emitting device 120 and the driver 110, thereby protecting the light emitting device 120 and the driver 110 from moisture and external shock. The molding 14 may further include a filler such as silica, TiO₂, alumina, or the like. The molding 14 may be formed to cover both the upper surface and the side surface of the light emitting device 120. The molding 14 may be formed as a molding layer having transmissivity.

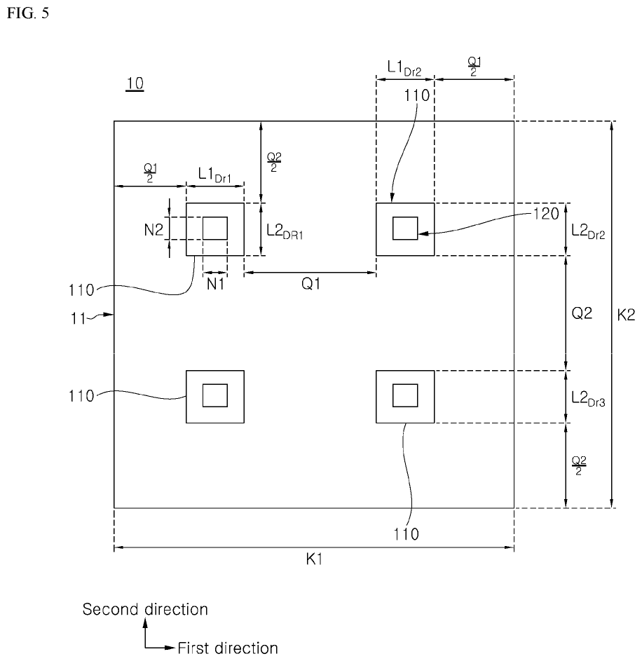

FIG. 5 is a plan view of the light emitting module 100 of FIG. 1, in which the drivers 110 may be disposed on a surface of the substrate 11. The plurality of drivers 110 may be disposed in various patterns, for example, in a grid pattern. On the first surface of each driver 110, the light emitting devices 120 may be vertically overlapped with one another.

In this case, first and second direction lengths L1Dr1, L2Dr1, L1Dr2, L2Dr2, L1Dr3, and L2Dr3 of the driver 110 may be longer than first and second direction lengths N1 and N2 of the light emitting device 120. Herein, L1Dr1, L1Dr2, and L1Dr3 may be referred to as a first direction length of each driver 110, and L2Dr1, L2Dr2, and L2Dr3 may be referred to as a second direction length of each driver 110.

For example, the first direction lengths L1Dr1 and L1Dr2 of the driver 110 may be 200 μm to 1000 μm. The second direction lengths L2Dr1 and L2Dr2 of the driver 110 may be 200 μm to 1000 μm. The first direction length N1 of the light emitting device 120 may be 100 μm to 900 μm. The second direction length N2 of the light emitting device 120 may be 100 μm to 900 μm.

First and second direction intervals Q1 and Q2 between adjacent drivers 110 on a surface of the substrate 11 may be 1 time or more and 3 times and less of one side length L1Dr1, L2Dr1, L1Dr2, L2Dr2, L1Dr3, or L2Dr3 of the driver 110. The transparency of the light emitting module 100 may be improved by making the intervals Q1 and Q2 between the drivers 110 sufficiently wide.

In addition, when an area of a rectangular region having first direction and the second direction lengths in the light emitting module 100 is referred to as a reference area, the transparency of the light emitting module 100 may be defined by Equation 1 below.

$$Equation 1$$

$$Transparency = \frac{Area occupied by all drivers disposed within reference area}{Reference area} \times 100$$

The transparency of the light emitting module defined by the Equation 1 may be 80% or more.

In this case, the reference area may be K1*K2, which is a specific area including at least 3 pixels. A first direction length K1 defining the reference area may be defined by Equation 2 below in which the first direction lengths L1Dr1 and L1Dr2 of two drivers 110 adjacent to each other in the first direction and the interval Q1 between two adjacent drivers 110 are used as variables. A second direction length K2 defining the reference area may be defined by Equation 3 below in which the second direction lengths L2Dr2 and L2Dr3 of two drivers 110 adjacent to each other in the second direction and the interval Q2 between two adjacent drivers 110 are used as variables.

K1=L1_{Dr2}+L1_{Dr3}+2Q1 Equation 2

K2=L2_{Dr2}+L2_{Dr3}+2Q2 Equation 3

The reference area may be defined by Equation 4 below.

Reference area=(L1_{Dr2}+L1_{Dr3}+2Q1)×(L2_{Dr2}+L2_{Dr3}+2Q2) Equation 4

For example, the K1 and the K2 may each be 2 inches, and the reference area may be 4 in2.

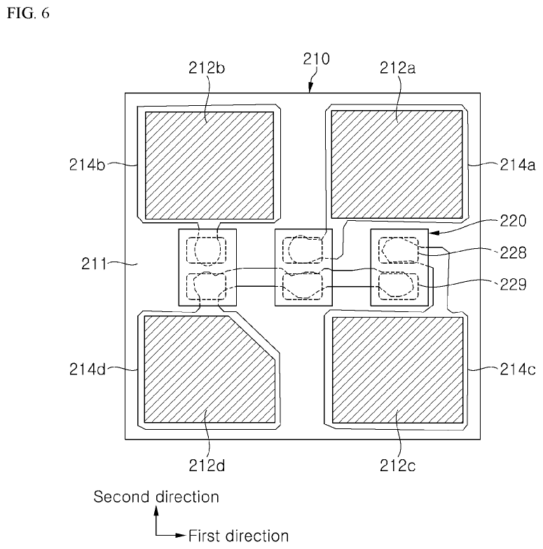

Meanwhile, structures of the light emitting device 120 and the driver 110 in the light emitting module 100 of FIGS. 1 through 5 is merely exemplary, and the present invention is not limited thereto. For example, a light emitting device 220 and a driver 210 of FIG. 6 illustrate a modified example of the light emitting device 120 and the driver 110 of FIG. 1.

The light emitting device 220 is provided in a plurality, and may be spaced apart in a transverse direction on a first surface of the driver 210. That is, a plurality of light emitting devices 220 may be spaced apart on the first surface of the driver 210. The light emitting device 220 may be configured to be identical or similar to that of FIG. 4, without being limited thereto. For example, the light emitting device 220 may include a single light emitting stack and emit light of a specific peak wavelength.

For example, as illustrated in FIG. 6, three light emitting devices 220 may be disposed on the first surface of the driver 210, and each of the light emitting devices 220 may emit light of peak wavelengths different from one another. The light emitting device 220 is a sub-pixel, and three light emitting devices 220 may form one pixel.

For example, one of the light emitting devices 220 may be a diode that emits blue light, may be a blue light emitting diode having a peak wavelength within a blue wavelength range, and a difference between the peak wavelength and a dominant wavelength of the blue light emitting diode may be between 2 nm and 15 nm. In detail, the blue light emitting diodes may have the peak wavelength between 430 nm and 475 nm, and may have the dominant wavelength between 460 nm and 480 nm. By keeping the difference between the peak wavelength and the dominant wavelength small, a color deviation may be reduced, thereby resulting in more vivid color expression. The peak wavelength of the blue light emitting diode may be a shorter wavelength than the dominant wavelength. Through this, it is possible to correct luminous efficacy while increasing light energy, thereby reducing a design difficulty.

As another example, one of the light emitting devices 220 may be a diode that emits green light, may be a green light emitting diode having a peak wavelength within a green wavelength range, and a difference between the peak wavelength and a dominant wavelength of the green light emitting diode may be between 5 nm and 20 nm. In detail, the green light emitting diode may have the peak wavelength between 510 nm and 540 nm, and may have the dominant wavelength between 525 nm and 545 nm. By keeping the difference between the peak wavelength and the dominant wavelength small, the color deviation may be reduced, thereby resulting in more vivid color expression. The peak wavelength of the green light emitting diode may be a shorter wavelength than the dominant wavelength. Through this, it is possible to correct the luminous efficacy while increasing light energy, thereby reducing the design difficulty.

As another example, one of the light emitting devices 220 may be a diode that emits red light, may be a red light emitting diode having a peak wavelength within a red wavelength range, and a difference between the peak wavelength and a dominant wavelength of the red light emitting diode may be between 5 nm and 30 nm. In detail, the red light emitting diode may have the peak wavelength between 620 nm and 640 nm, and may have the dominant wavelength between 600 nm and 630 nm. By keeping the difference between the peak wavelength and the dominant wavelength small, the color deviation may be reduced, thereby resulting in more vivid color expression. The peak wavelength of the red light emitting diode may be a longer wavelength than the dominant wavelength. Through this, it is possible to correct the luminous efficacy while increasing light energy, thereby reducing the design difficulty.

The light emitting device 220 may be configured to emit orange light, yellow light, purple light, or ultraviolet light in addition to blue light, green light, and red light.

The light emitting device 220 may include device electrodes 228 and 229. One of the device electrodes 228 and 229 may be a second conductivity type electrode 228 connected to a second conductivity type semiconductor layer of the light emitting stack, and the other may be a first conductivity type electrode 229 connected to a first conductivity type semiconductor layer of the light emitting stack.

In FIG. 6, the driver 210 may include a body portion 211, a first electrode portion 212 (212a, 212b, 212c, 212d) disposed on a first surface of the body portion, and a second electrode portion 213 (213a) disposed on a second surface of the body portion 211. Since the driver 210 may be configured similarly to the driver 110 of FIG. 1, a description of a redundant configuration is omitted.

The driver 210 may further include extension electrodes 214a, 214b, 214c, and 214d electrically connected to the first electrode portion 212 (212a, 212b, 212c, 212d). The driver 210 may be electrically connected to the device electrodes 228 and 229 of the light emitting device 220 through the extension electrodes 214a, 214b, 214c, and 214d.

One of the first electrode portions 212a, 212b, 212c, and 212d may be a first common electrode 212d connected to the first conductivity type electrode 229 of the light emitting devices 220. Remaining electrode portions may be first individual electrodes 212a, 212b, and 212c respectively connected to the second conductivity type device electrodes 228 of the light emitting device 220.

The extension electrode 214d connected to the first common electrode 212d may be a common extension electrode that is commonly connected to the first conductivity type electrodes 229 of the light emitting devices 220. The common extension electrode may extend along an arrangement direction of the light emitting devices 220. The extension electrodes 214a, 214b, and 214c respectively connected to the first individual electrodes 212a, 212b, and 212c may be individual extension electrodes connected to the second conductivity type electrode 228 of each of the light emitting devices 220.

FIG. 7 is a cross-sectional view of FIG. 6, in which the driver 210 may be disposed on a surface of a substrate 11. In FIG. 7, the first electrode portion 212 (212a, 212b, 212c, 212d) disposed on the first surface of the driver 210 may be a metal layer M. The second electrode portion 213 connected to a substrate electrode 12 may be disposed on a second surface of the driver 210.

The driver 210 may include the body portion 211 in which the first and second electrode portions 212 and 213 are disposed, and the metal layer M for electrical connection may be disposed within the body portion 211.

Accordingly, the substrate 11, the driver 210, and the light emitting device 220 are sequentially stacked, and the light emitting device 220 may be disposed on the first surface of the driver 210 to be vertically overlapped with the driver 210. Referring to FIG. 7, when a region of the driver 210 is referred to as IC and a pixel region including the light emitting devices 220 is referred to as PX in plan view, the IC region may be overlapped with the PX region. A ratio of cross-sectional areas in any cross section obtained by vertically cutting the PX region and the IC region may be 0.9 to 2 times. An area ratio of the PX region and an area ratio of the IC region on an upper surface of the PX region may be 0.8 to 4 times.

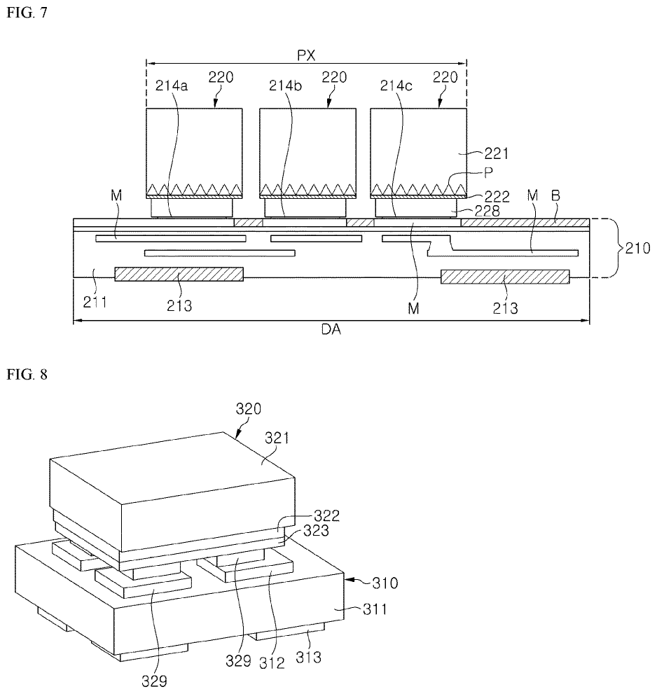

Next, FIGS. 8 through 10 are other modified examples of the light emitting device and the driver of FIG. 4. Light emitting devices 320, 420, and 520 and drivers 310, 410, and 510 of FIGS. 8 through 10 will be described in detail, focusing on differences from the light emitting device 120 and the driver 110 of FIG. 4.

First, in FIG. 8, one light emitting device 320 may be disposed on one driver 310, and the light emitting device 320 may include a substrate 321 and two light emitting stacks 322 and 323 vertically stacked. The two light emitting stacks 322 and 323 may emit light of peak wavelengths different from each other. A number of the light emitting stacks 322 and 323 is not limited to a specific number, and may be provided in three or more numbers.

The light emitting device 320 may include a device electrode 329 that is connected to the light emitting stacks 322 and 323 and mounted on a first electrode portion 312 of the driver 310.

The driver 310 may include a body portion 311, the first electrode portion 312 disposed on a first surface of the body portion 311, and a second electrode portion 313 disposed on a second surface of the body portion 311. The second electrode portion 313 of the driver 310 may be connected to a substrate electrode 12 of a substrate 11 in FIG. 1.

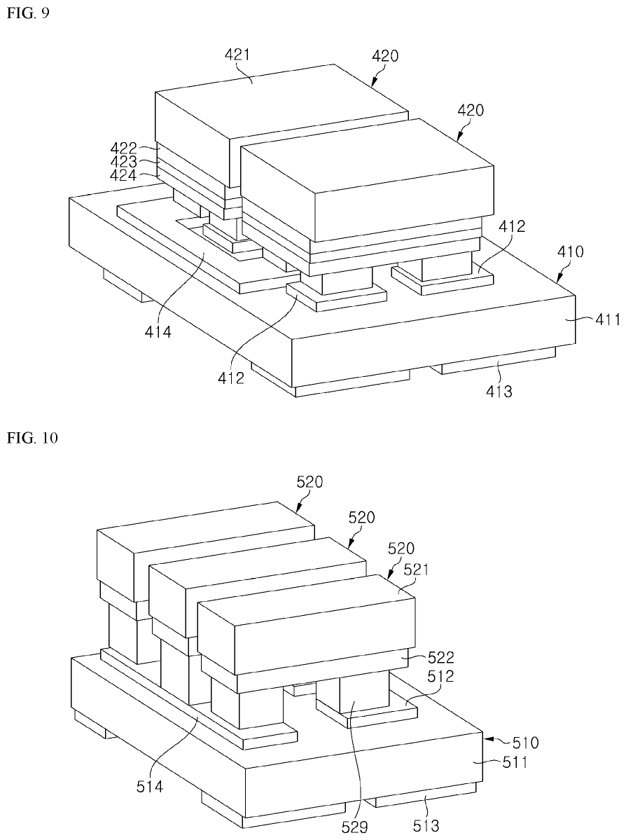

Next, in FIG. 9, two light emitting devices 420 are disposed on one driver 410, and each of the light emitting devices 420 may include a substrate 421 and three light emitting stacks 422, 423, and 424 vertically stacked. The three light emitting stacks 422, 423, and 424 may emit light of peak wavelengths different from one another.

The driver 410 may include a body portion 411, first electrode portions 412 and 414 disposed on a first surface of the body portion 411, and a second electrode portion 413 disposed on a second surface of the body portion 411. The second electrode portion 413 of the driver 410 may be connected to a substrate electrode 12 of a substrate 11.

In this case, the first electrode portions 412 and 414 may be provided in a plurality, and one of the first electrode portions 412 and 414 may be a first common electrode 414 that is commonly connected to two light emitting devices 420. The common electrode 414 may extend along an arrangement direction of the two light emitting devices 420.

Next, in FIG. 10, three light emitting devices 520 are disposed on one driver 510, and each of the light emitting devices 520 may include a substrate 521 and three light emitting stacks 522, 523, and 524 vertically stacked. The three light emitting stacks 522, 523, and 524 may emit light of peak wavelengths different from one another.

The driver 510 may include a body portion 511, first electrode portions 512 and 514 disposed on a first surface of the body portion 511, and a second electrode portion 513 disposed on a second surface of the body portion 511. The second electrode portion 513 of the driver 510 may be connected to a substrate electrode 12 of the substrate 11.

In this case, the first electrode portions 512 and 514 may be provided in a plurality, and one of the first electrode portions 512 and 514 may be a first common electrode 514 that is commonly connected to three light emitting devices 520. The common electrode 514 may extend along three light emitting devices 520. The common electrode 514 may be connected to first conductivity type semiconductor layers of the three light emitting devices 520. The common electrode 514 may be connected to a driving power source (Vdd).

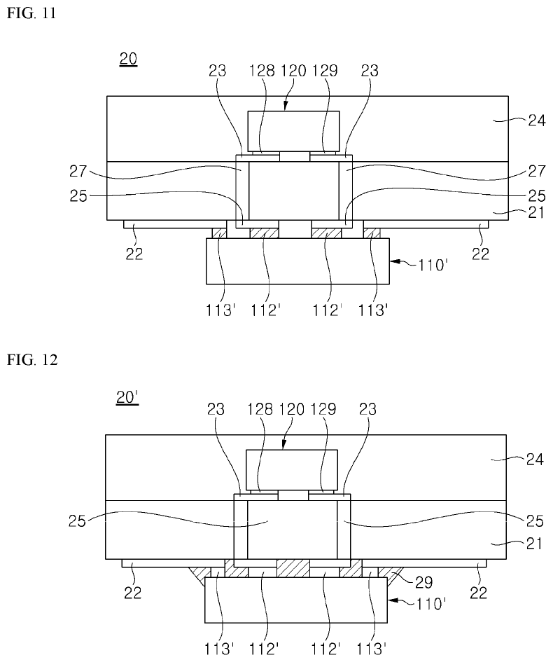

Next, FIG. 11 is a cross-sectional view showing a light emitting module 20 according to a second embodiment of the present invention. The light emitting module 20 of the second embodiment is described in detail, focusing on differences from the light emitting module 10 of the first embodiment. Meanwhile, the light emitting device 120 in FIG. 11 is not repeatedly described since it has been described in FIGS. 1 through 5, and it is apparent that the light emitting device 120 may be replaced with a modified example such as the light emitting devices 220, 320, 420, and 520 of FIGS. 6 through 10.

The light emitting module 20 may include one or more light emitting devices 120, a driver 110′ for driving the light emitting devices 120, and a substrate 21 on which the light emitting devices 120 and the driver 110′ are mounted. That is, the light emitting module 20 is different from the light emitting module 10 of the first embodiment in that the substrate 21 is disposed between the light emitting device 120 and the driver 110′.

When a surface of the substrate 21 on which the light emitting device 120 is disposed is referred to as a first surface, the driver 110′ may be disposed on a second surface opposite to the first surface of the substrate 21. In this case, the light emitting device 120 may be disposed on the first surface of the substrate 21, and the driver 110′ may be disposed on the second surface of the substrate 21 to be perpendicularly overlapped with the light emitting device 120 in plan view.

Referring to FIG. 11, the driver 110′ may include a first electrode portion 112′ connected to the light emitting device 120 and a second electrode portion 113′ connected to the substrate 21.

Unlike the driver 110 of FIG. 1, in which the first electrode portion 112 and the second electrode portion 113 are respectively disposed on the first surface and the second surface, the driver 110′ of FIG. 11 is different in that the first electrode portion 112′ and the second electrode portion 113′ are disposed on a same first surface. That is, the driver 110′ may include the first electrode portion 112′ disposed on a first surface of the driver 110′ and connected to the light emitting device 120, and the second electrode portion 113′ disposed on the first surface of the driver 110′ and connected to the substrate 21. In this case, the light emitting device 120 and the driver 110′ are spaced apart by a thickness of the substrate 21, thereby reducing a deterioration of the light emitting device 120 due to heat of the driver 110′ and improving a reliability of the light emitting device 120.

In this case, the substrate 21 may include a first substrate electrode 23 disposed on the first surface of the substrate 21 and connected to device electrodes 128 and 129 of the light emitting device 120, a second substrate electrode 22 disposed on the second surface of the substrate 21 and connected to the second electrode portion 113′, and a third substrate electrode 25 disposed on the second surface of the substrate 21 and connected to the first electrode portion 112′.

A through hole vertically passing through the substrate 21 may be formed, and the substrate 21 may further include a through electrode 27 that connects the first substrate electrode 23 and the third substrate electrode 25 through the through hole.

The light emitting device 120 may be connected to the driver 110′ through the first substrate electrode 23, the through electrode 27, the third substrate electrode 25, and the first electrode portion 112′.

The light emitting module 20 may also further include a molding 24 that covers an upper surface and side surfaces of the light emitting device 120. The molding 24 may be further disposed on the second surface of the substrate 21 to protect the driver 110′.

Next, FIG. 12 is a modified example of the light emitting module 20 according to the second embodiment, and a light emitting module 20′ of FIG. 12 may be configured to be identical or similar to the light emitting module 20 of FIG. 11, except that it further includes a filler (underfill) 29 that fills a space between a substrate 21 and a driver 110′. The filler 29 may reinforce an adhesive force of electrode portions 112′ and 113′ of the driver 110′, thereby preventing the driver 110′ from falling off the substrate 21 due to external force. The filler 29 may be applied only to a region that does not exceed 10% of a side length of the driver 110′ on a side surface of the driver 110′ so as not to reduce transparency.

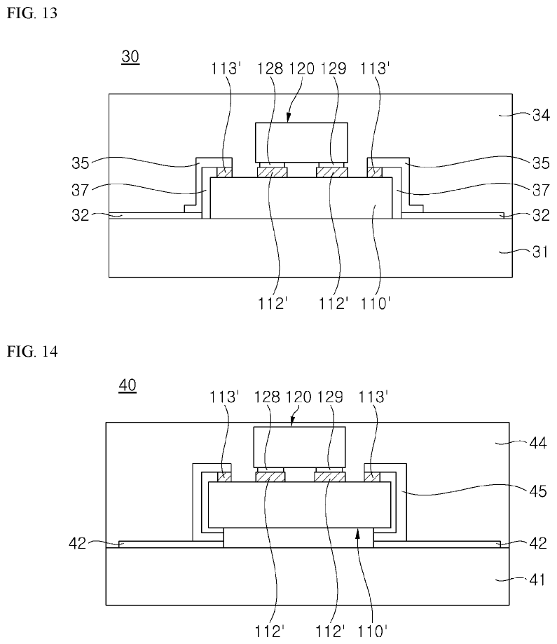

Next, FIG. 13 is a cross-sectional view showing a light emitting module 30 according to a third embodiment. The light emitting module 30 of the third embodiment is described in detail, focusing on differences from the light emitting module 10 of the first embodiment. The light emitting device 120 in FIG. 13 is not repeatedly described since it has been described in FIGS. 1 through 5, and it is apparent that the light emitting device 120 may be replaced with a modified example such as the light emitting devices 220, 320, 420, and 520 of FIGS. 6 through 10.

The light emitting module 30 may include one or more light emitting devices 120, a driver 110′ for driving the light emitting devices 120, and a substrate 31 on which the driver 110′ is mounted. The light emitting module 30 is similar to the light emitting module 10 of the first embodiment in that the light emitting device 120 and the driver 110′ are disposed on a first surface of the substrate 31. However, the light emitting module 30 is different from the light emitting module 10 of the first embodiment in that a first electrode portion 112′ and a second electrode portion 113′ of the driver 110′ are disposed on a same first surface of the driver 110′.

The first electrode portion 112′ and the second electrode portion 113′ may be disposed on the first surface of the driver 110′, and the light emitting device 120 may be disposed on the first surface of the first driver 110′. Device electrodes 128 and 129 of the light emitting device 120 may be connected to the first electrode 112′. When both the electrode portions 112′ and 113′ of the driver 110′ are disposed on the first surface of the driver 110′, a design difficulty may be reduced.

In this case, a substrate electrode 32 may be disposed on the first surface of the substrate 31. The light emitting module 30 may further include a side electrode portion 35 connecting the second electrode portion 113′ and the substrate electrode 32 along a side surface of the driver 110′. The side electrode portion 35 may be formed along the side surface of the driver 110′. The side electrode portion 35 may move heat generated by the driver 110′ to the side surface of the driver 110′ to improve thermal diffusion and improve the reliability of the light emitting device 120.

In addition, the light emitting module 30 may further include an insulation portion 37 disposed between the side electrode portion 35 and the driver 110′. The insulation portion 37 may be formed of an insulating material such as epoxy or silicone. The insulation portion 37 may improve heat diffusion by separating the side electrode portion 35 and the driver 110′ from each other, and may prevent the driver 110′ from being damaged by heat.

In FIG. 13, the driver 110′ may face the first surface of the substrate 31 on a second surface. The second surface of the driver 110′ may be in close contact with the first surface of the substrate 31. Both the driver 110′ and the light emitting device 120 are disposed on the first surface of the substrate 31, so a molding 34 may cover and protect the driver 110′ and the light emitting device 120 at once with a single layer, thereby reducing the design difficulty.

Next, FIG. 14 is a cross-sectional view showing a light emitting module 40 according to a fourth embodiment. The light emitting module 40 of the fourth embodiment is described in detail, focusing on differences from the light emitting module 30 of the third embodiment. The light emitting device 120 in FIG. 14 is not repeatedly described since it has been described in FIGS. 1 through 5, and it is apparent that the light emitting device 120 may be replaced with a modified example such as the light emitting devices 220, 320, 420, and 520 of FIGS. 6 through 10.

The light emitting module 40 may be configured to be identical or similar to the light emitting module 30 of the third embodiment, except that a side electrode portion 45 extends to the second surface of the driver 110′.

As the side electrode portion 45 extends to the second surface of the driver 110′ and is connected to a substrate electrode 42, the second surface of the driver 110′ may be vertically spaced apart from a first surface of a substrate 41. Through this, it is possible to reduce damage to the substrate 41 when reworking the driver 110′. A molding 44 may be filled in a vertical space between the second surface of the driver 110′ and the first surface of the substrate 41. Through this, it is possible to prevent the driver 110′ from falling off due to air expansion when heated.

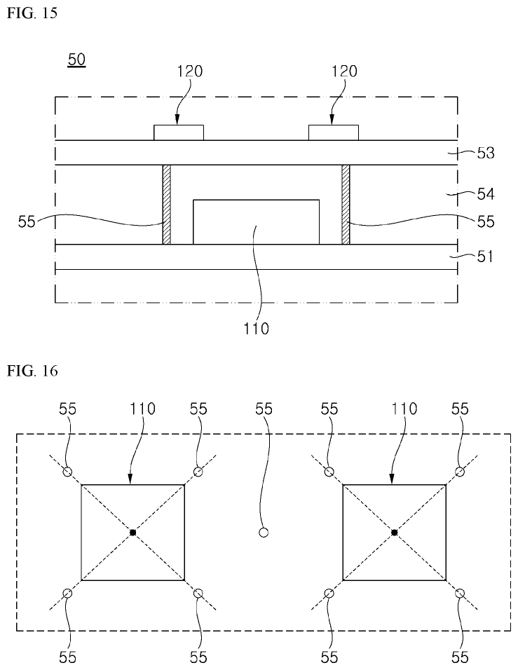

Next, FIG. 15 is a cross-sectional view showing a light emitting module 50 according to a fifth embodiment. The light emitting module 50 of the fifth embodiment is described in detail, focusing on differences from the previous embodiments. The driver 110 and the light emitting device 120 in FIG. 15 are not repeatedly described since they have been described in FIGS. 1 through 5, and it is apparent that the light emitting device 120 may be replaced with a modified example such as the light emitting devices 220, 320, 420, and 520 of FIGS. 6 through 10.

In detail, the light emitting module 50 may include a first substrate 51, the driver 110 mounted on a surface of the first substrate 51 for driving the light emitting device 120, a second substrate 53 opposite to the first substrate 51 at a distance, one or more light emitting devices 120 mounted on a surface of the second substrate 53, one or more connection electrodes 55 disposed between the first substrate 51 and the second substrate 53 to electrically connect the driver 110 and the light emitting devices 120, and a molding layer 54 filling a space between the first substrate 51 and the second substrate 53.

The light emitting module 50 differs from the previous embodiments in that the driver 110 mounted on the first substrate 51 and the light emitting device 120 mounted on the second substrate 53 are physically spaced apart from each other, but it has a structure where at least a portion of the light emitting device 120 is vertically overlapped with the driver 110 in plan view, and includes one or more connection electrodes 55 connecting therebetween. Through this, thermal isolation is possible in which the first substrate 51 and the second substrate 53 block the heat generated by the driver 110 from being directly transferred to the light emitting device 120, and the deterioration of the light emitting device 120 may be prevented and the reliability may be improved.

The first substrate 51 is a substrate for mounting the driver 110, and the driver 110 may be mounted on a surface thereof. The first substrate 51 may include a circuit pattern for supplying power to the driver 110 and transmitting a signal. In addition, the first substrate 51 may serve as a mechanical support base.

The first substrate 51 may be a printed circuit board (PCB), without being limited thereto, and for example, may be a substrate such as a glass substrate, or a substrate such as PET (Polyethylene Terephthalate) or PI (Polyimide).

The second substrate 53 may be disposed to be opposite to the first substrate 51 at a distance. One or more light emitting devices 120 may be mounted on a surface of the second substrate 53.

The second substrate 53 may be formed of a material having transmissivity such as glass, sapphire, PMMA (Polymethyl Methacrylate), PC (Polycarbonate), or the like to transmit light emitted from the light emitting device 120 to the outside.

The connection electrode 55 is disposed in a separation space between the first substrate 51 and the second substrate 53, and can be configured in various ways as an electrode that electrically connects the driver 110 and the light emitting device 120. The connection electrode 55 may not only serve as an electrical path, but also have various additional functions. In addition, a structure of the connection electrode 55 has a simpler and more cost-effective manufacturing process compared to a method of forming fine vias on a substrate, thereby improving a productivity of the light emitting module 50.

For example, the connection electrode 55 may be a pillar or post-shaped electrode perpendicularly extending from a surface of the first substrate 51 toward the second substrate 53, as illustrated in FIG. 15. As another example, the connection electrode 55 may be a pillar or post-shaped electrode perpendicularly extending from a surface of the driver 110 toward the second substrate 53.

The connection electrode may be formed in a manner by using a metallic wire, or by dispensing and curing a conductive paste or ink.

One end of the connection electrode 55 may be electrically connected to an electrode pad formed on the first substrate 51 or the driver 110, and the other end may be electrically connected to an electrode pad formed on a surface of the second substrate 53. Through this, an output signal of the driver 110 may be transmitted to the light emitting device 120 through wirings of the connection electrode 55 and the second substrate 53.

In addition, the connection electrode 55 may function as a structural support that maintains a constant distance between the first substrate 51 and the second substrate 53. Through this, it is possible to increase durability against external physical impacts and protect the structure from stress that may occur during the expansion and contraction of each component due to heat generated from the driver 110 or others, thereby preventing a decrease in reliability such as delamination.

In addition, in a case where the connection electrode 55 is formed of a material with high thermal conductivity such as metal, it may function as a heat dissipation path that effectively transfers heat generated from the driver 110 to the second substrate 53 or to the outside.

FIG. 16 shows an example of an arrangement of the connection electrode 55 in plan view. As illustrated in the drawing, a plurality of connection electrodes 55a, 55b, 55c, and 55d may be distributed and disposed around a periphery, particularly near four corners, avoiding a center of the driver 110. Alternatively, they may be disposed on a diagonal of the driver 110. Such a structure, in which the connection electrodes are distributed and disposed in the periphery, is advantageous for maximizing structural support across an entire module with a minimal area, and securing an efficient heat dissipation path while avoiding interference with the driver's active circuit region.

In addition, an additional connection electrode 55 may be disposed in a space between adjacent drivers 110. The additional connection electrode 55 may function as a structural support that reinforces mechanical strength. In addition, the additional connection electrode 55 may function as a part of a wide-area power grid or ground grid that distributes common power or ground. Through this, it is possible to simplify a complex power wiring design while supplying stable power to multiple drivers 110.

The molding layer 54 may fill remaining space between the first substrate 51 and the second substrate 53. The molding layer 54 may be formed of a transparent insulating resin with favorable light transmittance, such as silicone, epoxy, or the like. In a case where the driver 110 is disposed on a surface of the first substrate 51 facing the second substrate 53, the driver 110 may be covered by the molding layer 54. In a case where the light emitting device 120 is disposed on a surface of the second substrate 53 facing the first substrate 51, the light emitting device 120 may be covered by the molding layer 54.

In a case of FIG. 15, it is structure where the driver 110 is disposed on a surface of the first substrate 51 facing the second substrate 53, and the molding layer 54 may fill the space between the first substrate 51 and the second substrate 53, and be formed to cover at least a side surface of the connection electrode 55 and a side surface of the driver 110, thereby performing an encapsulation function to protect them from external moisture or contamination.

In an embodiment, the molding layer 54 may be flattened through a process such as grinding for its upper surface to have a same height as that of the end of the connection electrode 55. Through the flat surface, it is possible to provide a basis for the second substrate 53 to be stably attached and improve an ease of manufacturing.

Although the present disclosure has been described above with reference to preferred embodiments, it will be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

10, 10′, 20, 30, 40: Light emitting module
110, 110′, 210, 310, 410, 510: Driver
120, 220, 320, 420, 520: Light emitting device
130: Controller
111, 211, 311, 411, 511: Body portion
112, 112a, 112b, 112c, 112d, 112′, 212a, 212b, 212c, 212d, 312, 412, 512: First electrode portion
113a, 113b, 113c, 113d, 113′, 213, 313, 413, 513: Second electrode portion
121, 221, 321, 421, 521: Substrate
122, 123, 124, 222, 322, 323, 422, 423, 424, 522: Light emitting stack
128, 129, 228, 229, 329, 429, 529: Device electrode
125: Insulation layer
214a, 214b, 214c, 214d: Extension electrode
14, 24, 34, 44: Molding
12, 22, 23, 25, 32, 42: Substrate electrode
27: Through electrode

1. A light emitting module, comprising:
one or more light emitting devices;
a driver for driving the one or more light emitting devices; and
a substrate on which the driver is mounted,
wherein a light emitting device of the one or more light emitting devices is disposed on a first surface of the driver to vertically overlap with the driver.

2. The light emitting module of claim 1,
wherein the driver includes a first electrode portion disposed on the first surface and connected to a device electrode of the light emitting device, and a second electrode portion disposed on a second surface opposite to the first surface and connected to a substrate electrode of the substrate.

3. The light emitting module of claim 2, further comprising:
a plurality of light emitting devices including the one or more light emitting devices,
wherein the plurality of light emitting devices are spaced apart from one another on the first surface of the driver.

4. The light emitting module of claim 3,
wherein the first electrode portion includes a first common electrode commonly connected to the plurality of light emitting devices and a plurality of first individual electrodes respectively connected to the plurality of light emitting devices.

5. The light emitting module of claim 4,
wherein the light emitting device includes a plurality of light emitting stacks that are vertically stacked and configured to emit light of peak wavelengths different from one another.

6. The light emitting module of claim 5,
wherein the first electrode portion includes a first common electrode commonly connected to the plurality of light emitting stacks and a plurality of first individual electrodes respectively connected to the plurality of light emitting stacks.

7. The light emitting module of claim 1,
wherein an area occupied by the light emitting device disposed on the first surface of the driver is smaller than that of the first surface of the driver.

8. The light emitting module of claim 1, further comprising:
a molding part covering the light emitting device and the driver.

9. The light emitting module of claim 1,
wherein the driver includes a first electrode portion disposed on the first surface and connected to the device electrode of the light emitting device, a second electrode portion disposed on the first surface and connected to the substrate electrode of the substrate, and a side electrode portion connecting the second electrode portion and the substrate electrode along a side surface of the driver.

10. The light emitting module of claim 9,
wherein the driver faces the substrate on the second surface opposite to the first surface.

11. The light emitting module of claim 10, further comprising:
an insulation layer disposed between the side surface of the driver and the side electrode portion.

12. The light emitting module of claim 10,
wherein the side electrode portion extends to the second surface of the driver.

13. The light emitting module of claim 1,
wherein, when an area of a rectangular region having a width and a height of 2 inches each is referred to as a reference area, a transparency of the light emitting module defined by Equation 1 is 80% or more, wherein the Equation 1 is:
$$Transparency = \frac{Area occupied by all drivers disposed within reference area}{Reference area} \times 100.$$

14. The light emitting module of claim 1,
wherein an interval between adjacent drivers is between 1 and 3 times a length of one side of the driver.

15. A light emitting module, comprising:
one or more light emitting devices;
a driver for driving the one or more light emitting devices; and
a substrate on which the one or more light emitting devices and the driver are mounted,
wherein a light emitting device of the one or more light emitting devices is disposed on a first surface of the substrate, and the driver is disposed on a second surface opposite the first surface of the substrate to be perpendicularly overlapped with the light emitting device in plan view.

16. The light emitting module of claim 15,
wherein the driver includes a first electrode portion disposed on a first surface of the driver and connected to the light emitting device, and a second electrode portion disposed on the first surface of the driver and connected to the substrate.

17. The light emitting module of claim 16,
wherein the substrate includes a first substrate electrode disposed on the first surface of the substrate and connected to a device electrode of the light emitting device, a second substrate electrode disposed on the second surface of the substrate and connected to the second electrode portion, and a third substrate electrode disposed on the second surface and connected to the first electrode portion.

18. The light emitting module of claim 17,
wherein the substrate includes a through hole vertically passing through the substrate, and a through electrode connecting the first substrate electrode and the third substrate electrode through the through hole.

19. The light emitting module of claim 16, further comprising:
a filler that fills a space between the substrate and the driver.

20. A light emitting module, comprising:
a first substrate; a driver mounted on a surface of the first substrate for driving a light emitting device;
a second substrate opposite to the first substrate;
one or more light emitting devices mounted on a surface of the second substrate;
one or more connection electrodes disposed between the first substrate and the second substrate to electrically connect the driver and the one or more light emitting devices; and
a molding layer filling a space between the first substrate and the second substrate,
wherein at least a portion of the light emitting device is perpendicularly overlapped with the driver in plan view.
